(19) United States
(12) Patent Application Publication
(10) Pub. No.: US 2001/0044214 A1
(43) Pub. Date: Nov. 22, 2001

(54) Method for dry-etching a titanium nitride containing multilayer film

(76) Inventor: Mitsutaka Izawa, Tokyo (JP)

Correspondence Address: Helfgott & Karas PC, Empire State Bulding 60th Floor, New York, NY, 10118, US

(21) Appl. No.: 09/546,485

(22) Filed: Apr. 10, 2000

(30) Foreign Application Priority Data
Apr. 8, 1999 (JP) 11-101473

(51) Int. Cl. H01L 21/302; H01L 21/461

(52) U.S. Cl. 438/712

(57) ABSTRACT

In a method for dry-etching a multilayer film which contains a titanium nitride film and which is formed on a silicon dioxide layer, after the multilayer film is etched by using a Cl₂/BCl₃/CHF₃ gas while using a resist as a mask, but before the resist is ashed for removal of the resist, an overetching is carried out using a gas containing at least 50% of SF₆, thereby to elevate removability of the resist by the ashing.

### BACKGROUND OF THE INVENTION

The present invention relates to a process for fabricating a semiconductor device, and more specifically to a method for dry-etching a titanium nitride containing multilayer film formed on a silicon dioxide layer, using a resist as a mask.

Aluminum (Al) and tungsten (W) are used for interconnections in a semiconductor device. In this case, a multilayer film is often formed to have a lower layer formed of a titanium nitride (TiN). On the other hand, in a recent DRAM (dynamic random access memory), it is now considered to form a capacitor dielectric film of a tantalum oxide (Ta₂O₅). In this case, it is also considered to change the material of a capacitor electrode from a conventional polysilicon to a metal multilayer film such as W/Ti.

In the prior art, in the case of etching a multilayer film including a TiN film, at least TiN is etched with a gas such as Cl₂/BCl₃/CHF₃, containing chlorine (Cl) as a main element, and then, is over-etched with a gas which contains chlorine (Cl) as a main element but which does not contain SF₆. However, a deposition of TiCl generated when TiN is etched, hampers removal of a resist in a succeeding ashing process. This problem is remarkable in a large area pattern such as a capacitor plate.

Therefore, in order to elevate removability of the resist, a countermeasure has been used in which a fluorine containing gas is added in an ashing gas to volatilize the deposition of TiCl, with the result that the removability is improved. For example, the ashing is carried out by using a gas including 1% of CF₄ added to O₂. However, this has become a cause which disturbs the atmosphere within an asher and which fluctuates an ashing rate. Therefore, an etching method is demanded which can elevate removability of the resist without using a fluorine containing gas in the ashing process.

Now, the above mentioned problem of the prior art will be described with reference to the drawings. A first example of a prior art method for etching a multilayer film including a TiN film will be described with reference to FIGS. 1A to 1C.

FIG. 1A is a diagrammatic partial sectional view of a semiconductor device, illustrating a condition in which, on an interlayer insulator film 1 formed of SiO₂, in the named order, a Ta₂O₅ film 2 (which is provided in the case of a capacitor plate electrode but which is not provided for an aluminum interconnection) is formed by a CVD (chemical vapor deposition), a TiN film 3 is formed by a CVD or a sputtering, and an AlCu film 4 and a TiN film 5 are formed by a sputtering, and a resist 6 is deposited and patterned.

In this condition, a multilayer film (2+3+4+5) including the TiN film is etched using the patterned resist 6 as a mask. In this case, this etching is carried out by using Cl₂/BCl₃/CHF₃ or Cl₂/BCl₃/CH₂F₂, which is conventionally used in an etching process for AlCu or TiN. For example, the TiN/AlCu/TiN film is etched with a gas flow rate of Cl₂/BCl₃/CHF₃=70/40/7 sccm, a pressure of 8 mTorr, a source power of 1200 W and a bias power of 120 W, and succeedingly, an overetching is carried with the same type of etching gas. As a result, a construction as shown in FIG. 1B is obtained.

Thereafter, an ashing is carried out by use of an in-line asher. For example, the patterned resist 6 is removed by the ashing with a gas flow rate of O₂/N₂=3000/200 sccm, a pressure of 2 Torr, and a RF power of 1000 W. As a result, a construction as shown in FIG. 1C is obtained. However, particularly in a large-area pattern such as a capacitor plate, a problem that a residue 7 is apt to remain is encountered in this prior art process. This residue 7 includes the remaining resist and the deposition containing Ti.

Here, as mentioned above, a fluorine containing gas can be added to an ashing gas to elevate removability of the resist. However, this has become a cause which disturbs the atmosphere within the asher and which fluctuates an ashing rate.

Now, a second example of a prior art method for etching a multilayer film including a TiN film will be described with reference to FIGS. 2A to 2D.

FIG. 2A is a diagrammatic partial sectional view of a semiconductor device, illustrating a condition in which, on an interlayer insulator film 8 formed of SiO₂, in the named order, a TiN film 9 is formed by a CVD or a sputtering, and an W or WN film 10 is formed by a CVD, and a resist 11 is deposited and patterned.

In this condition, a multilayer film (8+9+10) including the TiN film is etched using the patterned resist 11 as a mask. In a first step, the etching is carried out by using SF₆/CHF₃/N₂, which is conventionally used in an etching process for W or WN. For example, the W or WN film is etched with a gas flow rate of SF₆/CHF₃/N₂=90/20/10 sccm, a pressure of 10 mTorr, a source power of 1200 W and a bias power of 60 W. As a result, a construction as shown in FIG. 2B is obtained.

In a second step, the etching is carried out by using Cl₂/BCl₃/CHF₃ or Cl₂/BCl₃/CH₂F₂, which is conventionally used in an etching process for TiN. For example, the TiN film is etched with a gas flow rate of Cl₂/BCl₃/CHF₃=70/40/7 sccm, a pressure of 8 mTorr, a source power of 1200 W and a bias power of 120 W. Succeedingly, an overetching is carried with the same type of etching gas. As a result, a construction as shown in FIG. 2C is obtained.

Thereafter, an ashing is carried out by use of an asher. For example, the patterned resist 11 is removed by the ashing with a gas flow rate of O₂/N₂=3000/200 sccm, a pressure of 2 Torr, and a RF power of 1000 W. As a result, a construction as shown in FIG. 2D is obtained. However, particularly in a large-area pattern such as a capacitor plate, a problem that a residue 12 is apt to remain is encountered even in this second prior art process. This residue 12 includes the remaining resist and the deposition containing Ti, similarly to the residue 7.

Here, as mentioned above, a fluorine containing gas can be added to an ashing gas to elevate removability of the resist. However, this has become a cause which disturbs the atmosphere within the asher and which fluctuates an ashing rate.

As mentioned above, in the prior art process, the residue is apt to remain after the ashing of the resist. The reason for this is that: It was an ordinary practice to use a chlorine containing gas such as Cl₂/BCl₃/CHF₃ for etching the TiN film. In this case, a Cl radical which is an etchant, reacts with Ti, so that TiCl is deposited on the resist. This deposition of TiCl hampers removal of the resist by the ashing.

In addition, in the case of adding a fluorine containing gas to an ashing gas, an F radial reacts with the deposition of TiCl to generate a volatile reaction product of TiF, with the result that the deposition of TiCl is removed, and therefore, removability of the resist is elevated. However, the addition of the fluorine containing gas disturbs the atmosphere within the asher and fluctuates an ashing rate. This is a problem to be avoided in the prior art.

### BRIEF SUMMARY OF THE INVENTION

Accordingly, it is an object of the present invention to provide an etching method for dry-etching a titanium nitride containing multilayer film, which has overcome the above mentioned problems of the prior art.

Another object of the present invention is to provide an etching method for dry-etching a titanium nitride containing multilayer film, which can elevate removability of the resist without using a fluorine containing gas in the ashing process.

The above and other objects of the present invention are achieved in accordance with the present invention by a method for dry-etching a titanium nitride containing multilayer film formed on a silicon dioxide layer, using a resist as a mask, characterized in that after the multilayer film is etched but before the resist is ashed for removal of the resist, an overetching is carried out using a gas containing at least 50% of SF₆, thereby to elevate removability of the resist by the ashing.

In the above mentioned method in accordance with the present invention for dry-etching the titanium nitride containing multilayer film, it is important that, before the resist is ashed for removal of the resist, the overetching is carried out using the gas containing at least 50% of SF₆. With this processing, a large amount of F radical can be dissociated from SF₆. The F radial reacts with Ti to generate a volatile reaction product of TiF, with the result that the deposition of TiCl is efficiently removed. Therefore, removability of the resist in the ashing is elevated. This advantage cannot be obtained when the proportion of SF₆ included in the gas used for the overetching is less than 50%. On the other hand, the gas used for the overetching can be composed of only SF₆.

The above and other objects, features and advantages of the present invention will be apparent from the following description of preferred embodiments of the invention with reference to the accompanying drawings.

### BRIEF DESCRIPTION OF THE DRAWINGS

FIGS. 1A to 1C are diagrammatic partial sectional views of a semiconductor device, illustrating a first example of the prior art method for etching a multilayer film including a TiN film;

FIGS. 2A to 2D are diagrammatic partial sectional views of a semiconductor device, illustrating a second example of the prior art method for etching a multilayer film including a TiN film.

FIGS. 3A to 3D are diagrammatic partial sectional views of a semiconductor device, illustrating a first embodiment of the method in accordance with the present invention for etching a multilayer film including a TiN film; and

FIGS. 4A to 4E are diagrammatic partial sectional views of a semiconductor device, illustrating a second embodiment of the method in accordance with the present invention for etching the multilayer film including the TiN film.

### DETAILED DESCRIPTION OF THE INVENTION

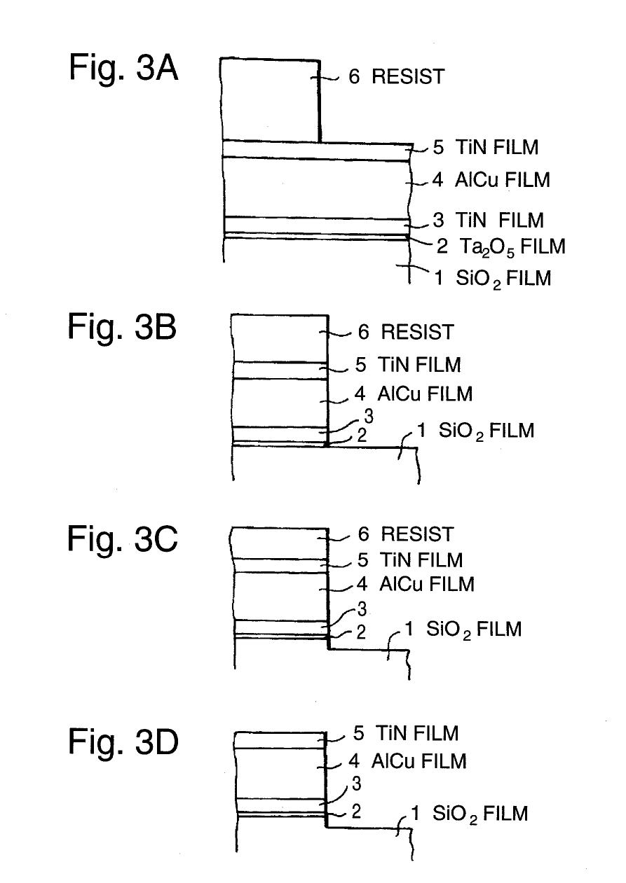

Now, a first embodiment of the method in accordance with the present invention for etching a multilayer film including a TiN film will be described with reference to FIGS. 3A to 3D, which are diagrammatic partial sectional views of a semiconductor device, for illustrating the first embodiment of the method in accordance with the present invention for etching the multilayer film including the TiN film.

FIG. 3A illustrates a condition in which, on an interlayer insulator film 1 formed of SiO₂, in the named order, a Ta₂O₅ film 2 (which is provided in the case of a capacitor plate electrode but which is not provided for an aluminum interconnection) is formed by a CVD, a TiN film 3 is formed by a CVD or a sputtering, and an AlCu film 4 and a TiN film 5 are formed by a sputtering, and a resist 6 is deposited and patterned.

In this condition, a multilayer film (2+3+4+5) including the TiN film is etched using the patterned resist 6 as a mask. In a first step, an etching is carried out by using Cl₂/BCl₃/CHF₃ or Cl₂/BCl₃/CH₂F₂, which is conventionally used in an etching process for AlCu or TiN. For example, the TiN/AlCu/TiN film is etched with a gas flow rate of Cl₂/BCl₃/CHF₃=70/40/7 sccm, a pressure of 8 mTorr, a source power of 1200 W and a bias power of 120 W. As a result, a construction as shown in FIG. 3B is obtained.

Succeedingly, in a second step, an overetching is carried with a gas containing at least 50% of SF₆. For example, the overetching is carried with a gas flow rate of SF₆/CHF₃=100/20 sccm, a pressure of 10 mTorr, a source power of 1000 W and a bias power of 60 W. As a result, a construction as shown in FIG. 3C is obtained.

Thereafter, an ashing is carried out by use of an in-line asher. For example, the patterned resist 6 is removed by the ashing with a gas flow rate of O₂/N₂=3000/200 sccm, a pressure of 2 Torr, and a RF power of 1000 W. As a result, a construction as shown in FIG. 3D is obtained.

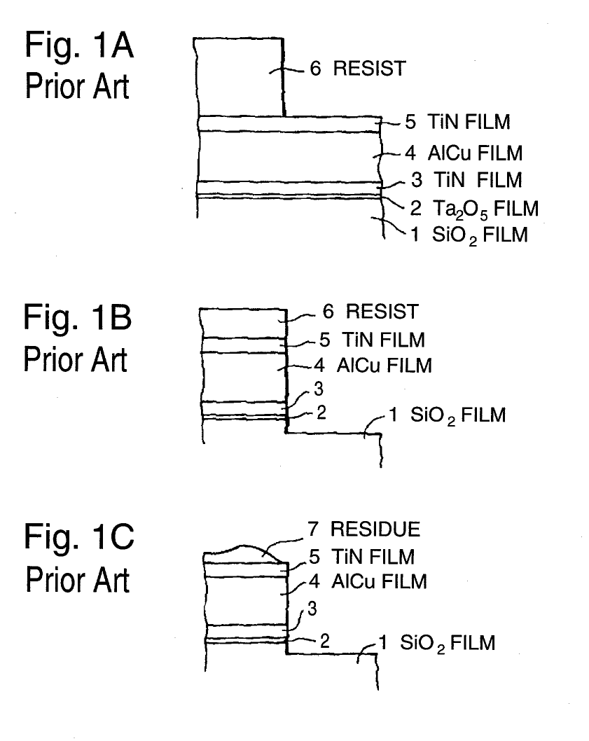

In this first embodiment, there remained no residue 7 which is apt to remain in the prior art process shown in FIGS. 1A to 1C.

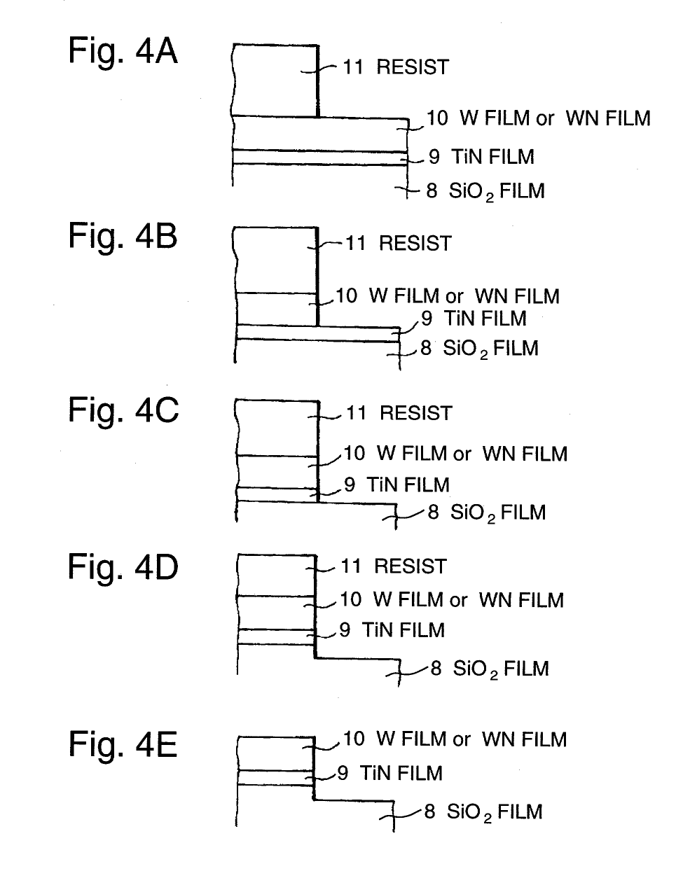

Next, a second embodiment of the method in accordance with the present invention for etching a multilayer film including a TiN film will be described with reference to FIGS. 4A to 4E, which are diagrammatic partial sectional views of a semiconductor device, for illustrating the second embodiment of the method in accordance with the present invention for etching the multilayer film including the TiN film.

FIG. 4A illustrates a condition in which, on an interlayer insulator film 8 formed of SiO₂, in the named order, a TiN film 9 is formed by a CVD or a sputtering, and an W or WN film 10 is formed by a CVD, and a resist 11 is deposited and patterned.

In this condition, a multilayer film (8+9+10) including the TiN film is etched using the patterned resist 11 as a mask. In a first step, the etching is carried out by using SF₆/CHF₃/N₂, which is conventionally used in an etching process for W or WN. For example, the W or WN film 10 is etched with a gas flow rate of SF₆/CHF₃/N₂=90/20/10 sccm, a pressure of 10 mTorr, a source power of 1200 W and a bias power of 60 W. As a result, a construction as shown in FIG. 4B is obtained.

In a second step, the etching is carried out by using Cl₂/BCl₃/CHF₃ or Cl₂/BCl₃/CH₂F₂, which is conventionally used in an etching process for TiN. For example, the TiN film 9 is etched with a gas flow rate of Cl₂/BCl₃/CHF₃=70/40/7 sccm, a pressure of 8 mTorr, a source power of 1200 W and a bias power of 120 W. As a result, a construction as shown in FIG. 4C is obtained.

Succeedingly, in a third step, an overetching is carried with a gas containing at least 50% of SF₆. For example, the overetching is carried with a gas flow rate of SF₆/CHF₃=100/20 sccm, a pressure of 10 mTorr, a source power of 1000 W and a bias power of 60 W. As a result, a construction as shown in FIG. 3D is obtained.

Thereafter, an ashing is carried out by use of an asher. For example, the patterned resist 11 is removed by the ashing with a gas flow rate of O₂/N₂=3000/200 sccm, a pressure of 2 Torr, and a RF power of 1000 W. As a result, a construction as shown in FIG. 4F is obtained.

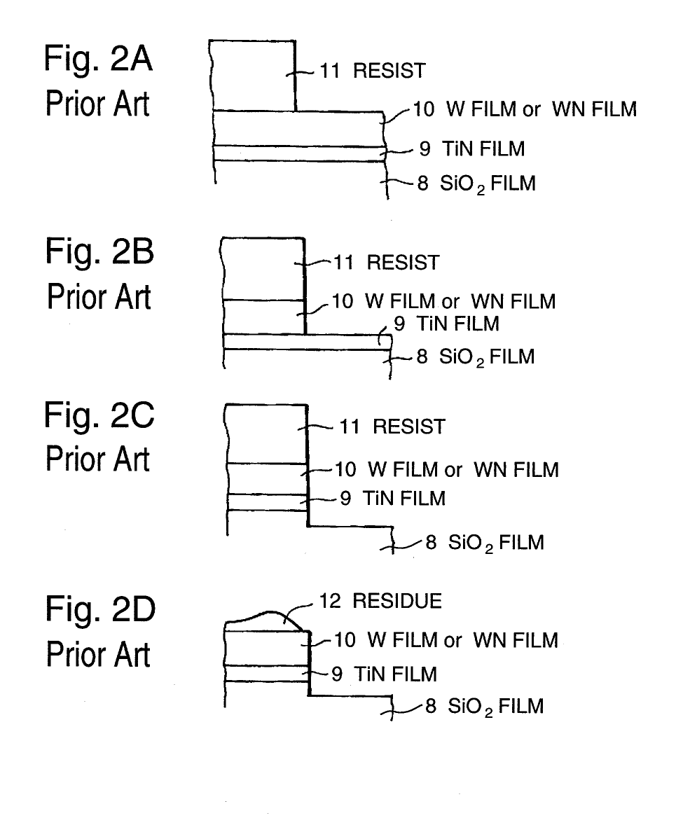

In this second embodiment, there remained no residue 12 which is apt to remain in the prior art process shown in FIGS. 2A to 2D.

In the above mentioned embodiments, the TiN containing multilayer film is constituted of the TiN film and the AlCu film or the TiN film and the W or WN film. However, the present invention cannot be limited to only these exemplified TiN containing multilayer films, but can be applied to any TiN containing multilayer film, for example, a multilayer film composed of a silicon film and a TiN film.

As mentioned hereinbefore, it was an ordinary practice to use a chlorine containing gas such as Cl₂/BCl₃/CHF₃ for etching the TiN film. In this case, a Cl radical which is an etchant, reacts with Ti, so that TiCl is deposited on the resist. In the present invention, however, the overetching is carried out using the gas containing at least 50% of SF₆. With this processing, a large amount of F dissociated from SF₆, reacts with Ti of TiCl to generate a volatile reaction product of TiF, with the result that the deposition of TiCl is efficiently removed. Therefore, removability of the resist in the ashing is elevated.

In the prior art, a fluorine containing gas can be added to an ashing gas to remove TiCl deposited on the resist. However, this causes another problem which disturbs the atmosphere within the asher and which fluctuates an ashing rate, also as mentioned hereinbefore. In the present invention, it is no longer necessary to add the fluorine containing gas to the ashing gas, so that there occurs no problem which disturbs the atmosphere within the asher and which fluctuates the ashing rate.

The method of the present invention can be applied to a large-area pattern such as a capacitor plate formed of the TiN containing multilayer film and also to a fine pattern such as interconnections formed of the TiN containing multilayer film. However, the method of the present invention is particularly advantageous in the case of patterning a large-area pattern such as a capacitor plate, since a large amount of deposition was deposited on the resist.

The invention has thus been shown and described with reference to the specific embodiments. However, it should be noted that the present invention is in no way limited to the details of the illustrated structures but changes and modifications may be made within the scope of the appended claims.

1. A method for dry-etching a titanium nitride containing multilayer film formed on a silicon dioxide layer, using a resist as a mask, characterized in that after the multilayer film is etched but before the resist is ashed for removal of said resist, an overetching is carried out using a gas containing at least 50% of SF₆, thereby to elevate removability of the resist by the ashing.

2. A method claimed in claim 1 wherein said titanium nitride containing multilayer film is constituted of a first titanium nitride film, an AlCu film and a second titanium nitride film stacked on said silicon dioxide layer in the named order.

3. A method claimed in claim 2 wherein said titanium nitride containing multilayer film constituted of said first titanium nitride film, said AlCu film and said second titanium nitride film is etched with an etching gas which contains chlorine as a main element, and said overetching is carried out using a SF₆/CHF₃ gas containing at least 50% of SF₆.

4. A method claimed in claim 3 wherein said etching gas is Cl₂/BCl₃/CHF₃ or Cl₂/BCl₃/CH₂F₂.

5. A method claimed in claim 1 wherein said titanium nitride containing multilayer film is constituted of a titanium nitride film and an W or WN film stacked on said silicon dioxide layer in the named order.

6. A method claimed in claim 5 wherein said titanium nitride containing multilayer film constituted of said titanium nitride film and said W or WN film is etched by a first etching step using SF₆/CHF₃/N₂ for etching said W or WN film and then by a second etching step using an etching gas which contains chlorine as a main element, for etching said titanium nitride film, and said overetching is carried out using a SF₆/CHF₃ gas containing at least 50% of SF₆.

7. A method claimed in claim 6 wherein said etching gas is Cl₂/BCl₃/CHF₃ or Cl₂/BCl₃/CH₂F₂.
